(19) United States
(12) Patent Application Publication
(10) Pub. No.: US 2026/0107741 A1
(43) Pub. Date: Apr. 16, 2026

(54) SUBSTRATE LIFTING MODULE, SUBSTRATE PROCESSING MODULE, AND SUBSTRATE PROCESSING SYSTEM HAVING THE SAME

(71) Applicant: PRESYS.CO.,LTD, Gyeonggi-do (KR)

(72) Inventor: Jae Hyun CHO, Gyeonggi-do (KR)

(73) Assignee: PRESYS.CO.,LTD, Gyeonggi-do (KR)

(21) Appl. No.: 19/115,253

(22) PCT Filed: Aug. 24, 2023
(86) PCT No.: PCT/KR2023/012568

§ 371 Date: Mar. 26, 2025

(30) Foreign Application Priority Data
Sep. 27, 2022 (KR) 10-2022-0122586

(51) Int. Cl. H10P 72/76

(52) U.S. Cl. CPC H10P 72/7618; H10P 72/7624; H10P 72/7626

(57) ABSTRACT

The present invention relates to a substrate raising/lowering module, a substrate processing module including the same, and a substrate processing system. A lifting module includes: a substrate support disposed in an interior space and supporting a substrate; and an upward/downward driving unit coupled to the substrate support to drive upward/downward movement of the substrate support, wherein the upward/downward driving unit includes a shaft coupled to the substrate support and extending outwardly through a chamber, and an anti-rotation member coupled to the shaft to prevent circumferential rotation of the shaft about a longitudinal reference axis of the shaft.

### TECHNICAL FIELD

The present invention relates to a substrate lifting module, and a substrate processing module and a substrate processing system having the same.

### RELATED ART

In general, a semiconductor substrate processing device performing a semiconductor manufacturing process and the like includes a plurality of process chambers in which a substrate processing process is carried out, a load-lock chamber generating an environment for a substrate to enter the process chamber before the substrate is introduced into the corresponding process chamber, and a transfer chamber connecting the process chambers to the load-lock chamber and installed with a robot arm adapted to deliver a substrate in the load-lock chamber to the process chamber or to deliver a substrate in the process chamber to the load-lock chamber.

The process chamber generally performs substrate processing at high temperature and at a near-vacuum process pressure. Since it is difficult to deliver the substrate at atmospheric pressure to the process chamber at high temperature and at the process pressure, it is necessary to create the same environment as the environment of the process chamber before the substrate is introduced into the process chamber, and this process is performed by the load-lock chamber.

That is, the load-lock chamber refers to a chamber that houses a substrate under substantially the same conditions as the environment of the process chamber or an external environment before the substrate is introduced into the process chamber from the outside or before the substrate is taken out of the process chamber.

A substrate processing chamber, such as the process chamber or the load-lock chamber, may be provided therein with a lifting module configured to lift or lower a substrate while supporting the substrate in the substrate processing chamber.

The substrate supported by the lifting module may be cooled by a heater plate or a cooling plate disposed within the load-lock chamber while being lifted or lowered by the lifting module.

The lifting module needs to be designed so as not to have a rotation degree of freedom in a circumferential direction when a movement direction for lifting and lowering is set to a reference axis direction.

However, a typical lifting module employs a large and complicated structure to maintain axial alignment between components and to constrain the rotation degree of freedom, resulting in an increased size of the lifting module and a more complicated design.

### SUMMARY OF INVENTION

### Technical Problem

It is an object of the present invention to provide a lifting module, which has a miniaturized and simple structure capable of providing lifting/lowering thrust while constraining a rotation degree of freedom in a circumferential direction, and a substrate processing module and a substrate processing system having the same.

### Solution to Problem

In accordance with one aspect of the present invention, there is provided a lifting module (200) disposed in a chamber (21) defining a sealed interior space (S) to lift or lower a substrate (G) introduced into the interior space (S) while supporting the substrate (G), the chamber (21) being provided with at least one gate (T) for entrance and exit of a substrate.

The lifting module (200) may include a substrate support (210) disposed in the interior space (S) and supporting the substrate (G), and an upward/downward driving unit (220) coupled to the substrate support (210) to drive upward/downward movement of the substrate support (210).

The upward/downward driving unit (220) may include a shaft (222) coupled to the substrate support (210) and extending outwardly through the chamber (21), and an anti-rotation member (228) coupled to the shaft (222) to prevent circumferential rotation of the shaft (222) about a longitudinal reference axis of the shaft (222).

The substrate support (210) may include a moving plate (212) disposed in the interior space (S) and at least one substrate seat (214) coupled to the moving plate (212) to support the substrate (G).

The substrate seat (214) may include a plurality of substrate seats.

The substrate support (210) may include a first substrate seat (214a) and a second substrate seat (214b) spaced apart from each other in an upward/downward direction and each supporting the substrate (G).

The shaft (222) may be coupled to a central region of the moving plate (212).

The upward/downward driving unit (220) may further include a cylinder (224) housing a shaft (222) coupled to the chamber (21) and extending outwards and a piston (226) coupled to the shaft (222) and movably disposed within the cylinder (224).

The anti-rotation member (228) may be disposed between the shaft (222) and the cylinder (224).

The upward/downward driving unit (220) may include a pneumatic source (229) delivering pneumatic pressure to a first space (V1) and a second space (V2) defined within the cylinder (224) and divided by the piston (226) to allow the piston (226) to move linearly within the cylinder (224).

The anti-rotation member (228) may include a ball spline member movably coupled to an outer circumferential surface of the shaft (222).

The lifting module (200) may further include a sealing block (230) disposed between the ball spline member (228) and the piston (226) to prevent leakage of the pneumatic pressure.

The ball spline member (228) may be fixed in its circumferential movement thereof relative to the longitudinal reference axis of the shaft (222).

The lifting module (200) may further include a locking key member (K) secured relative to the cylinder (224) and protruding toward a groove (228a) formed on an outer circumferential surface of the ball spline member (228) to lock the circumferential movement of the ball spline member (228).

In accordance with another aspect of the present invention, there is provided a substrate processing module (20) including: a chamber (21) defining a sealed interior space (S) and provided with at least one gate (T) for entrance and exit of a substrate; and the lifting module (200) disposed within the chamber (21) to lift or lower a substrate (G) introduced into the interior space (S) while supporting the substrate (G).

The substrate processing module (20) may be a load-lock module (20b).

The substrate processing module (20) may further include a gas injector (23) configured to inject an inert gas into the interior space (S); a gas discharge unit (24) configured to discharge the gas from the interior space (S); a heat exchanger (27) for temperature control of the substrate (G) introduced into the interior space (S); and a gate valve (25) opening or closing the gate (T).

The chamber (21) may include a partition wall (21c) dividing the interior space (S) to define a first interior space (S1) and a second interior space (S2) in an upward/downward direction.

The lifting module (200) may be provided to each of the first interior space (S1) and the second interior space (S2).

The chamber (21) may include two pairs of gates (T) corresponding to the first interior space (S1) and the second interior space (S2), respectively.

In accordance with a further aspect of the present invention, there is provided a substrate processing system including: at least one process module (20a) configured to perform substrate processing on a substrate (G) at a preset process pressure; a load-lock module (20b) configured to deliver the substrate (G) between the process module (20a) and an exterior at atmospheric pressure; and a transfer module (30) configured to deliver the substrate (G) between the process module (20a) and the load-lock module (20b).

At least one of the process module (20a) and the load-lock module (20b) may be provided with the lifting module (200).

### Effects of Invention

The lifting module according to the present invention, the substrate processing module and the substrate processing system having the same can realize a miniaturized and simple structure that has sufficient thrust for lifting or lowering and is capable of constraining a rotation degree of freedom in a circumferential direction.

Specifically, by adopting an anti-rotation structure in which a shaft moved upwards or downwards by a piston is integrally formed with a moving plate of a substrate support, the lifting module according to the present invention does not require a separate structure for constraining the rotation degree of freedom of the shaft or offsetting the circumferential rotation of the shaft, thereby realizing a miniaturized and simpler structure.

### BRIEF DESCRIPTION OF DRAWINGS

FIG. 1 is a plan view of a substrate processing system according to one embodiment of the present invention.

FIG. 2 is a side view of a substrate processing module of the substrate processing system shown in FIG. 1.

FIG. 3A is a plan view of a lifting module provided to the substrate processing module of FIG. 2, taken in an X-Z direction, FIG. 3B is a plan view of the lifting module provided to the substrate processing module of FIG. 2, taken in a Y-Z direction, and FIG. 3C is a plan view of the lifting module provided to the substrate processing module of FIG. 2, taken in an X-Y direction.

FIG. 4A is a cross-sectional view taken along line A-A of FIG. 3C, showing a substrate moved upwards by the lifting module.

FIG. 4B is a cross-sectional view taken along line A-A of FIG. 3C, showing a substrate moved downwards by the lifting module.

FIG. 5 is an exploded perspective view showing a shaft and a piston of the lifting module of FIG. 4A.

FIG. 6A is a perspective view of a sealing block coupled to the shaft of FIG. 5.

FIG. 6B is a cross-sectional view taken along line B-B of FIG. 6A.

FIG. 6C is a plan view of the sealing block of FIG. 6A, taken in an X-Y direction.

FIG. 7 is a perspective view of the sealing block shown in FIG. 6A.

FIG. 8 and FIG. 9 are views of typical lifting modules each disposed in a substrate processing module.

### DESCRIPTION OF EMBODIMENTS

Hereinafter, a lifting module according to the present invention, as well as a substrate processing module and a substrate processing system including the same, will be described with reference to the accompanying drawings.

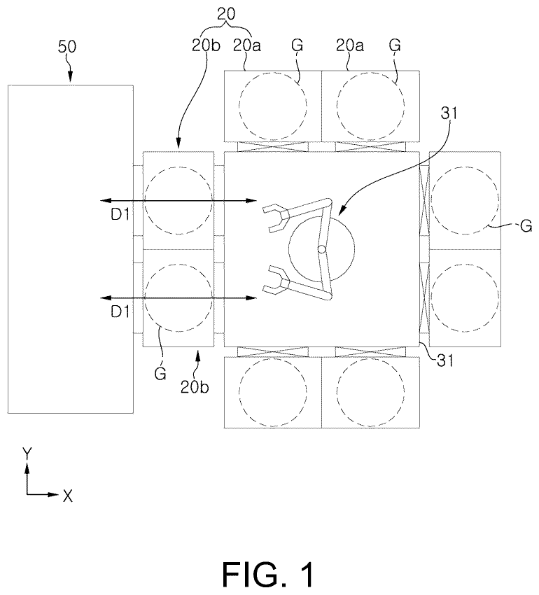

First, referring to FIG. 1, a substrate processing system according to the present invention may include at least one substrate processing module (20) that performs substrate processing on a substrate (G) at a preset process pressure.

The substrate processing module (20) refers to a unit module in which substrate processing is performed on a substrate, and may have various configurations depending on the type of substrate processing being performed.

Here, substrate processing is not limited to particular processes, such as cleaning, polishing, transferring, heating, cooling, oxidizing, lithography, etching, deposition, and the like.

In addition, the substrate (G) to be processed is a base material, which may be formed of various materials such as glass or semiconductors, for example, silicon or gallium, and is not limited to a particular material or shape.

For example, the substrate (G) may broadly refer to a wafer (including a bare wafer) as a semiconductor substrate for formation of semiconductor layers, such as an integrated circuit and the like.

The substrate processing module (20) may include process modules 20a each including at least one individual chamber (21) in which at least one process (deposition, etching, and the like) is carried out, and a load-lock module (20b) that delivers the substrate (G) between an exterior at atmospheric pressure and the process module (20a).

The substrate processing system may further include a transfer module (30) that transfers the substrate (G) between the process module (20a) and the load-lock module (20b).

Although the substrate processing system may be configured as a cluster type including the process modules (20a) and the transfer module (30) connecting the process modules (20a) in common, it should be understood that this structure is provided as one embodiment and the present invention is not limited thereto.

A gate valve operated to be opened or closed under control of a controller (not shown) may be disposed between the transfer module (30) and each individual chamber (21).

In addition, the transfer module (30) may be provided with a substrate delivery robot (31) configured to deliver the substrate (G) from the load-lock module (20b) to a predetermined location.

The process module (20a) refers to a module in which various processes, such as an etching process or a deposition process using plasma reaction or chemical vapor deposition, are performed, and may include a pressure regulation valve for regulation of vacuum pressure in an actual process after the process module (20a) is evacuated to a vacuum state by a vacuum pump (not shown) as a preliminary operation for the process.

Specifically, the process module (20a) may include a chamber (21) defining a closed processing space in which substrate processing is performed, a substrate support (not shown) that supports the substrate (G), a process gas injector (not shown) that injects a process gas, and a heating jacket (not shown) that controls the temperature of the process module (100).

On the other hand, the process module (20a) may include a plurality of individual chambers (21) to define a plurality of substrate processing spaces in which substrate processing, such as deposition, etching, and the like, is performed.

The plurality of process modules 20a may be disposed side by side along a side surface of the transfer module (30).

In this embodiment, the process module (20a) may include the plurality of individual chambers (21) to realize the plurality of substrate processing spaces, in which a single chamber (21) has two separate substrate processing spaces therein. Alternatively, a single process module (20a) may be configured to treat a single substrate (G).

The transfer module (30) is disposed between the load-lock module (20b) and the process module (20a) and may various configurations capable of conveying the substrate (G) to each of the substrate processing spaces of the process module (20a).

The transfer module (30) may include a chamber body formed with a plurality of gates through which the substrate (G) passes, and defining a space in which the substrate (G) is delivered between the load-lock module (20b) and the process module (20a).

The transfer module (30) may transfer the substrate (G), which is delivered from the load-lock module (20b), to the process module (20a) for substrate processing, or may transfer the substrate (G), which is delivered from the process module (20a) after substrate processing is completed, to the load-lock modul (20b).

Specifically, the transfer module (30) may be provided with a substrate delivery robot (31) that extracts the substrate (G) from the load-lock module (20b) to deliver the substrate (G) to a predetermined location and extracts the substrate (G) from the process module (20a) to deliver the substrate (G) to the load-lock module (20b).

The substrate delivery robot (31) is provided to the transfer module (30) and may have various configurations capable of delivering the substrate (G) between each of the process modules 20a and the transfer module (30) through the plurality of gates.

The substrate delivery robot (31) delivers the substrate (G), which is delivered from the load-lock module (20b), to each individual chamber (21) through the gate, and delivers the substrate (G), which is delivered from each individual chamber (21) of the process module (20a) through the gate, to the load-lock module (20b).

The transfer module (30) may be maintained at a process pressure close to vacuum at all times.

However, in order to minimize flow of particles from the process module (20a) into the transfer module (30) or from the transfer module (30) to the process module (20a) during delivery of the substrate (G), the internal pressure of the transfer module (30) may be maintained in a relatively higher state (low vacuum) than the internal pressure of the process module (20a).

The load-lock module (20b) may be configured in a variety of ways including configurations that allow the load-lock module (20b) to be exposed to an environmental condition close to an environmental condition within the transfer module (30) while blocking the environmental condition within the transfer module (30) from being influenced from the outside.

That is, the load-lock module (20b) may be changed from a near-vacuum process pressure state to an atmospheric pressure state or from the atmospheric pressure state to the process pressure state.

In addition, the load-lock module (20b) may house the substrate (G) sent from a loading unit (50) connected to an external site, for example, a substrate storage container (not shown), under atmospheric pressure.

The load-lock module (20b) may be coupled at one side thereof to the loading unit (50) and at the other side thereof to the transfer module (30).

After the substrate (G) is delivered from the substrate storage container (FOUP) in a standby state through the loading unit (50), the interior of the load-lock module (20b) is changed to a near-vacuum process pressure state as in the transfer module (30).

Further, when the substrate (G) processed in the process module (20a) is delivered to the load-lock module (20b) through the transfer module (30), the interior of the load-lock module (20b) is changed to an atmospheric pressure state in order to allow the substrate (G) to be delivered to an external substrate storage container (FOUP) through the loading unit (50).

As shown in FIG. 1, the load-lock modules (20b) may be provided as a pair of load-lock modules disposed side by side on one side of the transfer module (30).

Specifically, each of the load-lock modules (20b) may include a chamber (21), which defines a sealed interior space(S) therein and is provided with at least one gate (T) for entrance and exit of the substrate.

The chamber (21) refers to a housing defining a sealed interior space(S) and provided with at least one gate (T) for entrance and exit of the substrate, and may have various configurations.

For example, the chamber (21) may include at least one pair of gates (T) for entrance and exit of the substrate, respectively, in which the pair of gates (T) may be formed in a substrate delivery direction (D1) (substrate transfer direction) of the substrate (G).

The substrate delivery direction (D1) may be defined as a direction parallel to a traveling path of the substrate (G) entering and exiting the chamber (21).

For example, the gates (T) refer to openings opened and closed by gate valves (25) described below and may include a first gate (T1) corresponding to the loading unit (50) and a second gate (T2) corresponding to the transfer module (300).

When the chamber (21) has a substantially hexahedral shape, the at least one pair of gates (T) may be provided to a pair of opposite sidewalls of the chamber (21).

When the chamber (21) includes a plurality of independent substrate processing regions, the gates (T) may be formed in plural corresponding to the substrate processing regions.

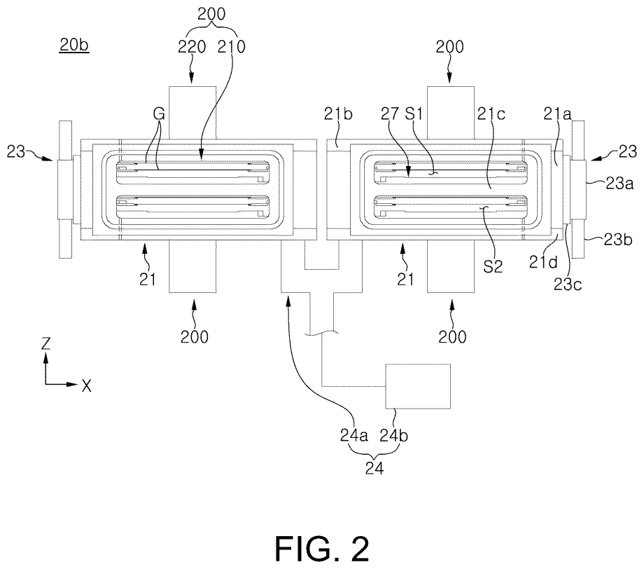

Although FIG. 1 and FIG. 2 illustrate an embodiment of the chamber (21) formed with two pairs of gates (T) spaced apart from each other in an upward/downward direction, it should be understood that the present invention is not limited thereto.

The chamber (21) may be formed in a variety of shapes, for example, in a rectangular (hexahedral) shape in plan view.

The chamber (21) may be configured to form a plurality of independent substrate processing regions or to process a plurality of substrates (G) in one substrate processing region.

The chamber (21) may include a chamber body (21a) open at an upper side thereof and an upper lid (21b) coupled to an upper surface of the chamber body (21a) to define an interior space (S) therein.

The chamber body (21a) may be realized by a single integral member.

When a lower surface of the chamber body (21a) is open, the chamber (21) may further include a lower lid (21d) coupled to the lower surface of the chamber body (21a).

For example, the chamber body (21a) may include a partition wall (21c) that divides the interior space (S) to define a first interior space (S1) and a second interior space (S2) in the upward/downward direction.

The first interior space (S1) and the second interior space (S2) may correspond to independent substrate processing regions.

The chamber body (21a) may include two pairs of gates (T) corresponding to the first interior space (S1) and the second interior space (S2), respectively.

The load-lock module (20b) may include a gas injector (23) configured to inject an inert gas into the interior space (S), a gas discharge unit (24) configured to discharge the gas from the interior space (S), a heat exchanger (27) for temperature control of the substrate (G) introduced into the interior space (S), and a gate valve (25) for opening or closing the gate (T).

The gas injector (23) may have various configurations capable of injecting the inert gas into the interior space (S).

The gas injector (23) may be provided to the chamber body (21a) to change the interior space (S) from a process pressure state to an atmospheric pressure state by injecting the inert gas into the interior space (S) and may also perform a cooling function to cool the substrate (G).

The inert gas may include a gas for venting/purging the interior space (S), for example, N₂ gas.

Although the inert gas is supplied for the purpose of pressure changing/purging the interior space of the chamber (21), the inert gas also serves to cool the substrate (G) to a predetermined temperature to prevent thermal damage to the substrate (G) that can occur when the substrate (G) heated in the process module (20a) is discharged in a heated state therefrom.

For example, the gas injector (23) may include a valve block (23a) having a gas flow path therein, at least one gas valve (23b) provided to the valve block (23a) to open or close the gas flow path, and a diffuser (not shown) that communicates with the gas flow path and through which the inert gas is injected into the interior space (S).

The gas flow path refers to a flow path along which the inert gas flows within the valve block (23a) and may form a single path or may be branched in various ways.

The gas valve (23b) refers to a shut-off valve provided to the valve block (23a) to open or close the gas flow path and may have various configurations.

When the interior space (S) of the chamber (21) of the load-lock module (20b) is divided into the first interior space (S1) and the second interior space (S2), the gas valve (23b) may be provided in plural corresponding to the first interior space (S1) and the second interior space (S2) in order to independently control gas injection into the first interior space (S1) and the second interior space (S2).

The diffuser (not shown) may have various configurations capable of injecting the gas into the interior space (S) and may communicate with the gas flow path to receive the inert gas and inject the inert gas into the interior space (S).

The gas discharge unit (24) may have various configurations capable of discharging the gas from the interior space (S) and may discharge the gas from the interior space to change the interior space (S) from an atmospheric pressure state to a process pressure state.

The gas discharge unit (24) may include a gas discharge line (24a) coupled to the chamber (21) and a vacuum pump (24b) coupled to the gas discharge line (24a).

When the substrate processing system includes a pair of load-lock modules (20b) as shown in FIG. 2, the gas discharge unit (24) may include a common discharge line for evacuating the load-lock modules (20b) using a single vacuum pump.

The heat exchanger (27) may have various configurations capable of performing temperature control (cooling or heating) of the substrate (G) introduced into the interior space (S).

When the interior space (S) of the chamber (21) of the load-lock module (20b) is divided into the first interior space (S1) and the second interior space (S2), the heat exchanger (27) may be provided to each of the first interior space (S1) and the second interior space (S2).

For example, the heat exchanger (27) may include a heat exchange plate formed in a planar shape corresponding to the substrate (G), a heating medium channel embedded in the heat exchange plate to allow a heating medium supplied from the outside to flow therein, and a heating medium port for supply and discharge of the heating medium to and from the heating medium channel, without being limited thereto.

As another example, the heat exchanger (27) may include a halogen lamp disposed to face the substrate (G).

In addition, the heat exchanger (27) may include both a heating plate for heating the substrate and a cooling plate for cooling the substrate.

The heat exchanger (27) may be coupled to the lids (21b, 21d) of the chamber (21). When a lifting module (200) described below is coupled to the lids (21b, 21d), the lifting module (200) and the heat exchanger (27) may be modularized and disposed through the lids (21b, 21d).

The gate valve (25) refers to a valve for opening or closing the gate (T) and may be integrally formed with the chamber (21) as a part of the load-lock module (20b).

On the other hand, the substrate processing module (20) may include the lifting module (200) disposed within the chamber (21) to lift or lower the substrate (G) introduced into the interior space (S) while supporting the substrate (G).

The lifting module (200) may be disposed anywhere within the substrate processing module (20), for example, in the process module (20a) and/or the load-lock module (20b).

Hereinafter, the lifting module (200) according to the present invention will be described with reference to an embodiment in which the lifting module (200) is disposed in the load-lock module (20b). However, it should be understood that an installation location of the lifting module (200) is not limited to the load-lock module (20b) and the lifting module (200) may be disposed anywhere within the substrate processing module (20) including the process module (20a).

The lifting module (200) is disposed within the chamber (21) and may have various configurations capable of lifting or lowering the substrate (G) introduced into the interior space (S) while supporting the substrate (G).

The lifting module (200), disposed in the chamber (21) and configured to support the substrate (G) introduced into the interior space (S), may be provided in plural corresponding to a plurality of substrate processing regions, when the chamber (21) includes the plurality of independent processing regions, as shown in FIG. 2.

That is, the lifting module (200) in an upper substrate processing region may be disposed on the upper lid (21b) of the chamber (21) and the lifting module (200) in a lower substrate processing region independent of the upper substrate processing region may be disposed on the lower lid (21d) of the chamber (21).

The lifting module (200) disposed on the lower lid (21b) may have the same or similar configuration to the lifting module (200) disposed on the upper lid (21b) and may be disposed in an upside-down configuration with respect to the lifting module (200) disposed on the upper lid (21b).

In one embodiment, the lifting module (200) may include a substrate support (210) disposed in the interior space (S) to support the substrate (G) and an upward/downward driving unit (220) coupled to the substrate support (210) to drive upward/downward movement of the substrate support (210).

Referring to FIG. 2 to FIG. 4B, the substrate support (210) may include a moving plate (212) disposed in the interior space (S) and at least one substrate seat (214) coupled to the moving plate (212) to support the substrate (G).

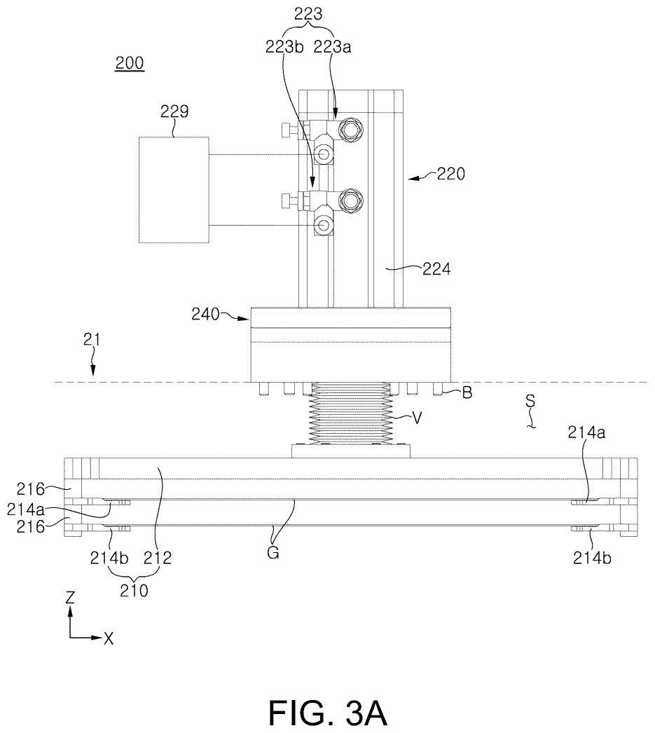

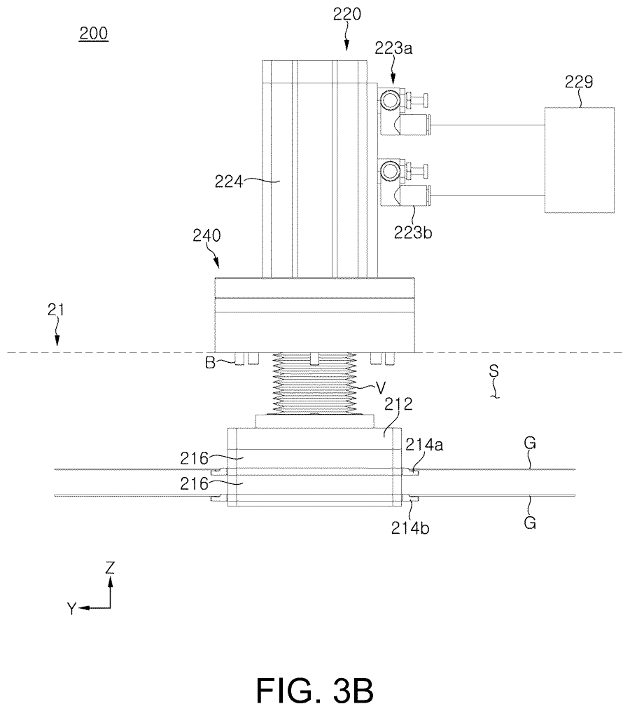

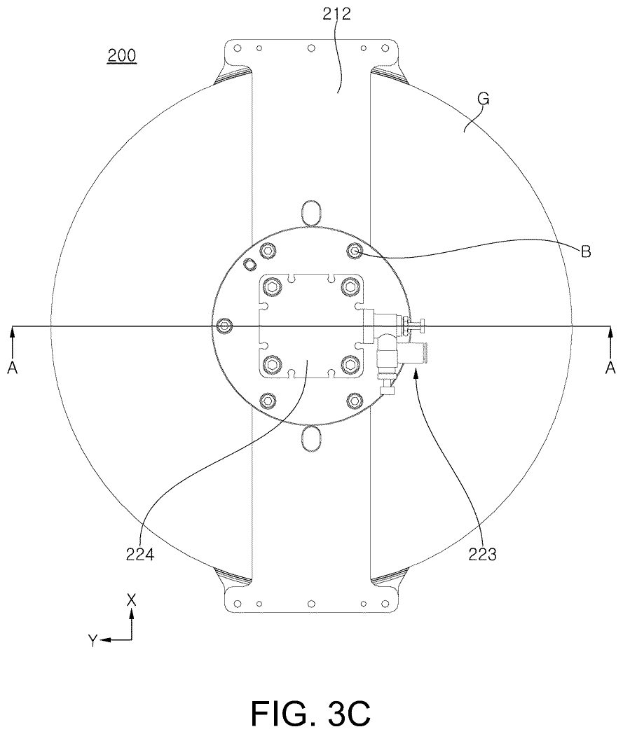

The moving plate (212) may have any shape so long as the moving plate is realized as a plate member disposed in the interior space (S) such that support members (214) described hereinafter can be disposed thereon. For example, the moving plate may have a bar shape with a constant width, as shown in FIG. 3C.

The substrate seat (214) refers to a support member coupled to the moving plate (212) to support the substrate (G) and may have various configurations and shapes.

The substrate seat (214) may include a pair of support members coupled to opposite ends of the moving plate (212) in a longitudinal direction thereof, respectively, so as to support an edge of a lower surface of the substrate (G).

The pair of support members may extend toward the center of the substrate (G) to be seated thereon to form a contact surface with the edge of the lower surface of the substrate (G) along extensions thereof.

A coupling member (216) extending in the upward/downward direction may be disposed between the substrate seat (214) and the moving plate (212) to couple the substrate seat (214) and the moving plate (212) while forming a gap between the substrate (G) and the moving plate (212) in the upward/downward direction.

The substrate seat (214) may be provided in plural. For example, the substrate seat (214) may include a first substrate seat (214a) and a second substrate seat (214b) spaced apart from each other in the upward/downward direction and each supporting the substrate (G).

Thus, as shown in FIG. 2, the substrate support (210) may be configured to support a plurality of substrates (G) spaced apart from each other in the upward/downward direction in a single substrate processing region.

The first substrate seat (214a) and the second substrate seat (214b) may have the same or similar configuration.

A coupling member (216) extending in the upward/downward direction may be further disposed between the first substrate seat (214a) and the second substrate seat (214b) to couple the first substrate seat (214a) and the second substrate seat (214b) to each other while forming a gap between the first substrate seat (214a) and the second substrate seat (214b) in the upward/downward direction.

The upward/downward driving unit (220) is coupled to the substrate support (210) to drive upward/downward movement of the substrate support (210) and may have various configurations.

For example, the upward/downward driving unit (220) may include a shaft (222) coupled to the substrate support (210) and extending outwardly through the chamber (21), and an anti-rotation member (228) coupled to the shaft (222) to prevent circumferential rotation of the shaft (222) with respect to a longitudinal reference axis of the shaft (222).

The shaft (222) is coupled to the substrate support (210) and extends outwardly through the chamber (21) and may have various configurations.

The shaft (222) is coupled at one end thereof to one surface of the moving plate (212) of the substrate support (210) and may extend in a longitudinal direction thereof to penetrate the lids (21b, 21d).

The one end of the shaft (222) may be coupled to a central region of the moving plate (212), which may coincide with the center of the substrate (G) being supported.

The shaft (222) may be secured to the moving plate (212) through a bolt member (B) and may have a one-piece design.

The shaft (222) may be driven in the upward/downward direction by various drive sources including pneumatic pressure, hydraulic pressure, and the like, without being limited thereto, and may have any structure for transmission of driving force so long as the shaft (222) can be moved upward/downward.

By way of example, the upward/downward driving unit (220) may be of a cylindrical type and may further include a cylinder (224) housing the shaft (222) coupled to the chamber (21) and extending outwardly therefrom, and a piston (226) coupled to the shaft (222) and movably disposed within the cylinder (224).

The cylinder (224) houses the shaft (222) coupled to the chamber (21) and extending outwardly therefrom, and may have various configurations.

The lifting module (200) may include a coupling block (240) and a plurality of bolt members (B) for coupling the cylinder (224) to the lids (21b, 21d) at the outside of the chamber (21).

The coupling block (240) is coupled to the cylinder (224) and may be coupled to the lids (21b, 21d) through the plurality of bolt members (B).

The cylinder (224) may have various shapes and structures so long as the cylinder (224) can house the shaft (222) extending outwardly from the chamber (21) and can define a space that allows the shaft (222) to move upwards or downwards therein.

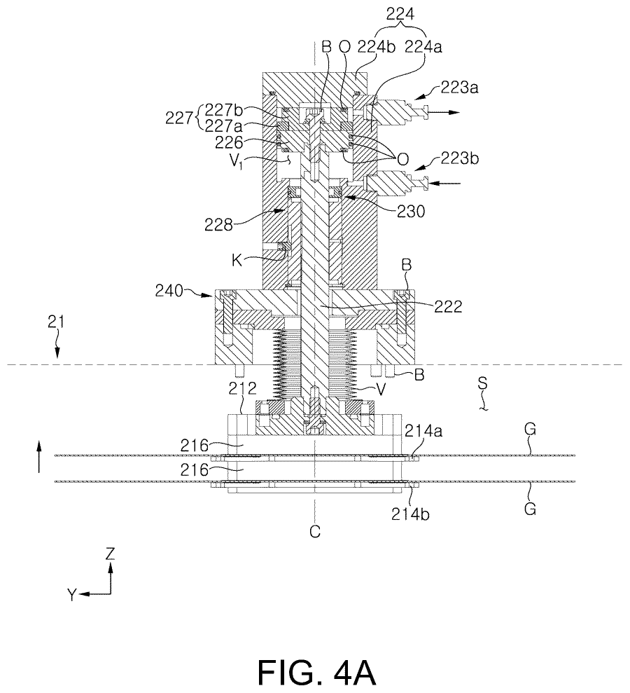

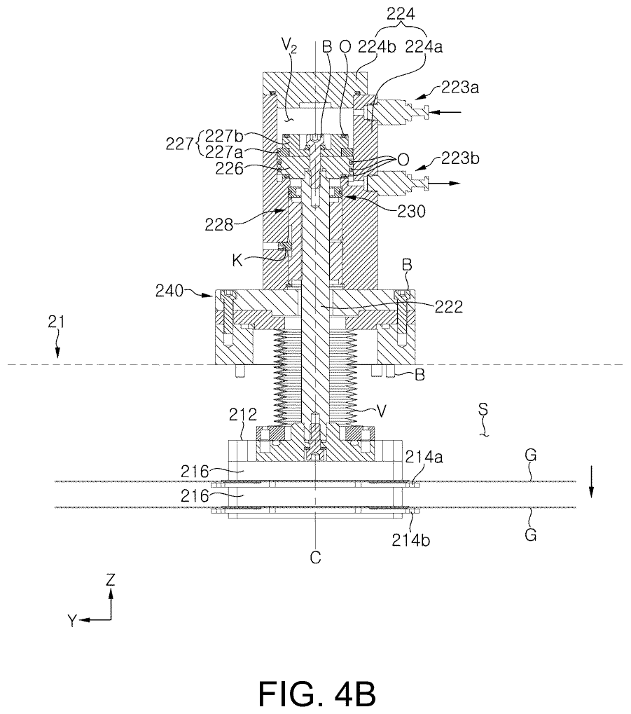

As shown in FIG. 4A and FIG. 4B, the cylinder (224) may include a cylinder body (224a) and a top cover (224b) that covers an open upper surface of the cylinder body (224a).

Referring to FIG. 3A to FIG. 4B, in order to seal the interior space(S) of the substrate processing module (20) despite upward/downward movement of the shaft (222), a bellows (V) may be disposed between the coupling block (240) and the moving plate (212) to surround the shaft (222).

The piston (226) is coupled to the shaft (222) and is movably disposed within the cylinder (224) and may have various configurations.

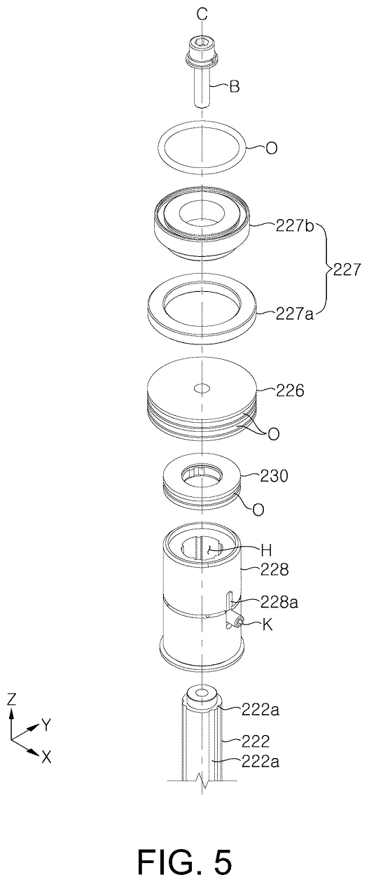

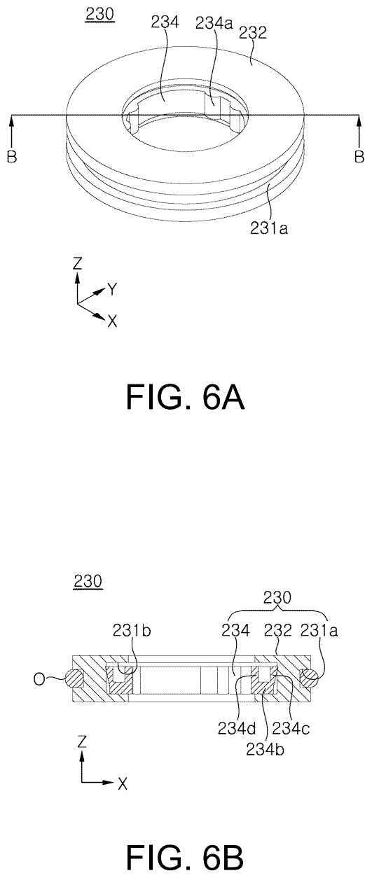

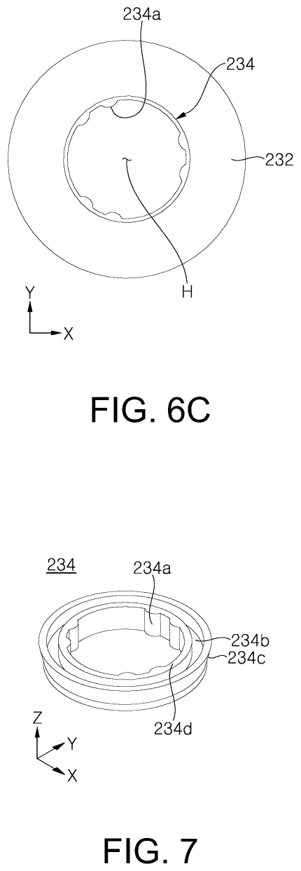

For example, referring to FIG. 4A and FIG. 5, the piston (226) may be secured to the other end of the shaft (222) by the bolt members (B) or may be formed in a hollow ring shape and secured to the shaft (222) so as to surround an outer circumferential surface of the shaft (222).

The piston (226) may closely contact an inner circumferential surface of the cylinder (224) and may be disposed to move upwards or downwards together with the shaft (222) within the cylinder (224).

At least one sealing member (O-ring) may be disposed along an outer circumferential surface of the piston (226) facing the cylinder (224).

The piston (226) may be further provided on a lower surface thereof with an O-ring member (O) for sealing.

The cylinder (224) may have a first space (V1) and a second space (V2) defined therein and divided by the piston (226).

Here, the upward/downward driving unit (220) may include a pneumatic source (229) that transfers pneumatic pressure to the first space (V1) and the second space (V2) to force the piston (226) to move linearly within the cylinder (224).

To this end, an outer wall of the cylinder (224) may be formed with two pressure transfer holes that communicate with the first space (V1) and the second space (V2), respectively. The two pressure transfer holes may be connected to the pneumatic source (229) through transfer valves (223a, 223b), respectively.

FIG. 4A shows the shaft (222) and the piston (226) moved upwards when pneumatic pressure is transferred to the first space (V1), and FIG. 4B shows the shaft (222) and the piston (226) moved downwards when pneumatic pressure is transferred to the second space (V2).

Upward/downward movement of the shaft (222) may be realized by the pneumatic source (229) and pneumatic control.

Although FIG. 3A to FIG. 4B show the pneumatic source (229) as a driving source, it should be understood that the driving source of the lifting module (200) according to the present invention is not limited thereto.

In addition, the piston (226) may be coupled to a magnetic portion (227).

The magnetic portion (227) may be superimposed on an upper surface of the piston (226) and may be coupled to the piston (226) and the shaft (222) by bolt members (B) for coupling to the other end of the shaft (222). However, it should be understood that a coupling manner of the magnetic portion (227) is not limited thereto.

Referring to FIG. 4A to FIG. 5, the magnetic portion (227) may include a magnet member (227a) seated on the upper surface of the piston (226) and a magnet guide member (227b) holding the magnet member (227a) in place and secured to the piston (226).

The magnetic guide member (227b) may be disposed on an upper surface thereof with an O-ring member (O).

The anti-rotation member (228) is coupled to the cylinder shaft (222) to prevent circumferential rotation of the shaft (222) about the longitudinal reference axis of the shaft (222) and may have various configurations.

In one embodiment, the anti-rotation member (228) may be disposed between the shaft (222) and the cylinder (224).

Here, the longitudinal direction of the shaft (222) is parallel to a movement (lifting or lowering) direction of the shaft (222) and is consistent with the z-axis direction in the drawings.

Here, the circumferential rotation means rotation about the longitudinal reference axis (C) of the shaft (222).

The anti-rotation member (228) may be realized by, for example, a ball member movably coupled to the outer circumferential surface of the shaft (222), as shown in FIG. 3A to FIG. 5.

The ball spline member (228) may be disposed within the cylinder (224) and may be a cylindrical member formed at a center thereof with a through-hole (H) through which the shaft (222) penetrates in the upward/downward direction.

The ball spline member (228) may be secured to a lower side of the cylinder (224) and may be constrained in movement with respect to the upward/downward direction and the circumferential direction.

That is, the ball spline member (228) may be fixed in its circumferential movement thereof relative to the longitudinal reference axis of the shaft (222).

Since the ball spline member (228) is secured in place with respect to the cylinder (224), the shaft (228) may be movably disposed with a longitudinal degree of freedom with respect to the ball spline member (228).

To this end, the ball spline member (228) may be formed with a groove (228a) formed on a lateral outer circumferential surface thereof and the cylinder (224) may be provided with a locking key member (K) on an inner wall thereof facing the groove (228a) such that the locking key member protrudes toward the groove (228a) and is placed within the groove (228a) to lock the circumferential movement of the ball spline member (228).

The locking key member (K) may be a type of set screw and may be secured in place with respect to the cylinder (224).

The groove (228a) may be realized in the form of an elongated hole extending in the longitudinal direction of the ball spline member (228).

The ball spline member (228) may have a plurality of protruding steel balls (not shown) rotatably disposed on an inner circumferential surface of the through-hole (H) and arranged in the longitudinal direction thereof. Since this structure of the ball spline member is a typical ball spline structure, the ball spline member will not be described in detail.

The shaft (222) may be formed on the outer circumferential surface thereof with grooves (222a) formed at locations corresponding to the steel balls in the longitudinal direction to provide rolling surfaces on which the steel balls of the ball spline member (228) can roll.

Since the steel balls protruding from the circumferential surface of the ball spline member (228) move in the grooves (222a) of the shaft (222) while rolling on the grooves (222a) of the shaft (222) in an shape engagement state therewith, the shaft (222) can move relative to the ball spline member (228) in the upward/downward direction while circumferential rotation thereof is constrained.

The lifting module (200) is configured to prevent leakage of pneumatic pressure in order to prevent loss of thrust for lifting and lowering. To this end, the lifting module (200) may further include a sealing block (230) between the ball spline member (228) and the piston (226).

Accordingly, the first space (V1) described above can be formed between the piston (226) and the sealing block (230), and the sealing block (230) can prevent the pneumatic pressure in the first space (V1) from leaking towards the ball spline member (228), thereby preventing loss of thrust for lifting or lowering of the lifting module (200).

The sealing block (230) may include a cylindrical body (232) fixedly disposed within the cylinder (224) and formed at a center thereof with a through-hole through which the shaft (222) penetrates in the upward/downward direction, and a shaft sealing member (234) closely contacting the outer circumferential surface of the shaft (222).

The cylindrical body (232) is formed on an outer circumferential surface thereof with a first groove (231a) extending in a circumferential direction thereof such that the sealing member (O) is disposed on the first groove (231a) to closely contact the inner circumferential surface of the cylinder (224).

One surface of the cylindrical body (231) may adjoin an upper surface of the ball spline member (228) and the other surface of the cylindrical body (231) may face the first space (V1).

The cylindrical body (232) may be formed on an inner circumferential surface thereof with a second groove (231b) extending in a ring shape in the circumferential direction thereof such that the shaft sealing member (234) formed in a ring shape is disposed on the second groove (231b) to closely contact the outer circumferential surface of the shaft (222).

The shaft sealing member (234) may be formed of a material suitable for sealing, such as synthetic rubber and the like, and may be, for example, a sealing member formed of FKM (Viton™).

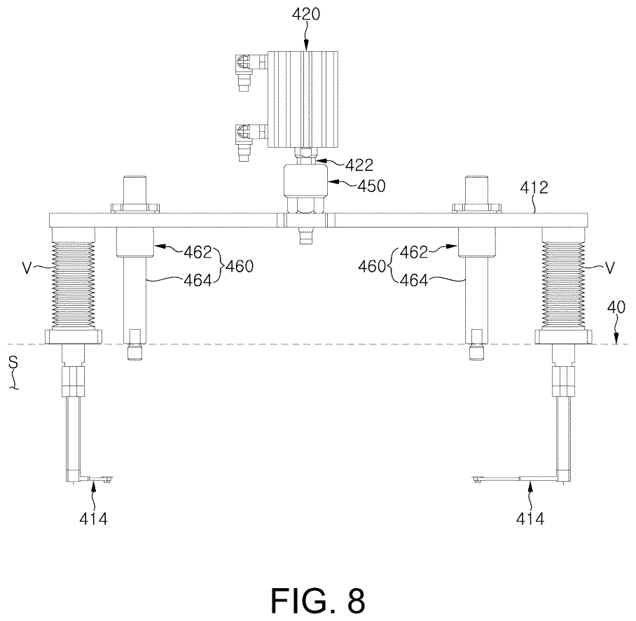

As shown in FIG. 7A and FIG. 8, the shaft sealing member (234) may be disposed in the second groove (231b) on the inner circumferential surface of the cylindrical body (232) to protrude toward the shaft (222).

The shaft sealing member (234) may be formed with a recess formed on one surface thereof facing the first space (V1) and depressed in the circumferential direction thereof, and may include an inner wall (234d) and an outer wall (234c) with the recess disposed as a boundary therebetween, and a bottom surface (234b) connecting the inner wall (234d) and the outer wall 234c as a bottom surface of the recess.

Accordingly, the shaft sealing member (234) may have a U-shaped cross-section.

An inner circumferential surface of the inner wall (234d) facing the shaft (222) may be formed with protrusions (234a) that engage with the grooves (222a) of the shaft (222) to closely contact the grooves (222a), whereby the shaft sealing member (234) can closely contact the shaft (222) without leakage.

An outer circumferential surface of the outer wall (234c) facing the cylindrical body (232) may be gradually sloped from the bottom surface (234b) to approach and contact the cylindrical body (232).

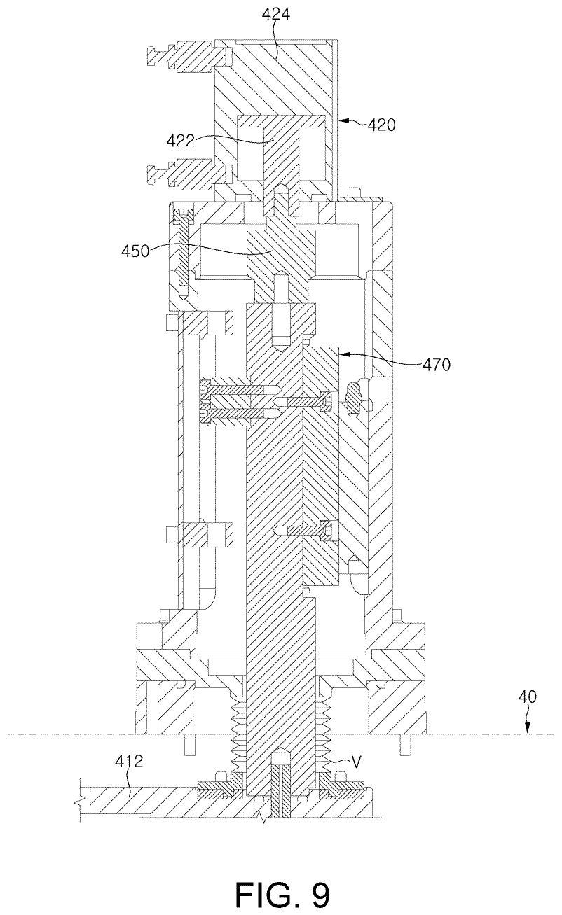

Referring to FIG. 8 and FIG. 9, a typical lifting module (400) disposed in a substrate processing module (40) is provided with a floating joint (450) to offset eccentricity in axial alignment of a shaft (422) and a moving plate (412), and is provided with a plurality of guide structures (460) using separate ball bushes (462) and linear shafts (464) disposed outside the substrate processing module (40), as shown in FIG. 8, or a large LM guide (470) disposed within a cylinder, as shown in FIG. 9, in order to constrain the rotation degree of freedom in a circumferential direction, thereby causing a complicated and large structure of the substrate processing module (40).

Referring to FIG. 8, the floating joint (450) is disposed for axial alignment between the shaft (422) and the moving plate (412), and, in order to constrain the rotation degree of freedom, the moving plate (412) is disposed outside the substrate processing module (40) and a plurality of separate linear guides (460) is further disposed between the moving plate (412) and an upper lid of the substrate processing module (40), thereby causing a complex structure and increase in height, overall size, and weight of the substrate processing module.

Referring to FIG. 9, the floating joint (450) is disposed for axial alignment between the moving plate (412) and the shaft (422) within the cylinder (424) and the large LM guide (470) is disposed between the floating joint 450 and the moving plate (412) in order to constrain the rotation degree of freedom, thereby causing a complex structure and increase in height, overall size, and weight of the substrate processing module.

Conversely, the lifting module (200) having the aforementioned configuration provides the structure capable of constraining the rotation degree of freedom in the circumferential direction thereof using the ball-spline (228), thereby providing a simple and minimized structure, and employs the sealing block (230) suitable for the ball-spline (288) to prevent a problem of thrust for lifting or lowering.

The lifting module (200) according to the present invention has an effect of preventing rotation of the shaft (222) while reducing the height of the lifting module (200) through a simple structure even without using the floating joint (450) as shown in FIG. 8 and FIG. 9, thereby reducing the overall size of the lifting module by 40% or more, as compared with a typical structure.

Although some embodiments have been described herein, it should be understood by those skilled in the art that these embodiments are given by way of illustration only and the present invention is not limited thereto. Therefore, the scope of the invention should be interpreted according to the following appended claims as covering all modifications or variations derived from the appended claims and equivalents thereto.

1. A lifting module disposed in a chamber defining a sealed interior space to lift or lower a substrate introduced into the interior space while supporting the substrate, the chamber being provided with at least one gate for entrance and exit of a substrate,
the lifting module comprising: a substrate support disposed in the interior space and supporting the substrate; and an upward/downward driving unit coupled to the substrate support to drive upward/downward movement of the substrate support,
wherein the upward/downward driving unit includes a shaft coupled to the substrate support and extending outwardly through the chamber, and an anti-rotation member coupled to the shaft to prevent circumferential rotation of the shaft about a longitudinal reference axis of the shaft

2. The lifting module according to claim 1, wherein the substrate support includes a moving plate disposed in the interior space and at least one substrate seat coupled to the moving plate to support the substrate.

3. The lifting module according to claim 2, wherein
the substrate seat includes a plurality of substrate seats, and
the substrate support includes a first substrate seat and a second substrate seat spaced apart from each other in an upward/downward direction and each supporting the substrate.

4. The lifting module according to claim 2, wherein the shaft is coupled to a central region of the moving plate.

5. The lifting module according to claim 1, wherein the upward/downward driving unit further includes:
a cylinder housing the shaft coupled to the chamber and extending outwards therefrom; and a piston coupled to the shaft and movably disposed within the cylinder.

6. The lifting module according to claim 5, wherein the anti-rotation member is disposed between the shaft and the cylinder.

7. The lifting module according to claim 5, wherein the upward/downward driving unit includes a pneumatic source delivering pneumatic pressure to a first space and a second space defined within the cylinder and divided by the piston to allow the piston to move linearly within the cylinder.

8. The lifting module according to claim 7, wherein the anti-rotation member includes a ball spline member movably coupled to an outer circumferential surface of the shaft.

9. The lifting module according to claim 8, further comprising:
a sealing block disposed between the ball spline member and the piston to prevent leakage of the pneumatic pressure.

10. The lifting module according to claim 8, wherein the ball spline member is fixed in its circumferential movement thereof relative to the longitudinal reference axis of the shaft.

11. The lifting module according to claim 10, further comprising:
a locking key member secured relative to the cylinder and protruding toward a groove formed on an outer circumferential surface of the ball spline member to lock the circumferential movement of the ball spline member.

12. A substrate processing module comprising: a chamber defining a sealed interior space and provided with at least one gate for entrance and exit of a substrate; and the lifting module according to claim 1, the lifting module being disposed within the chamber to lift or lower a substrate introduced into the interior space while supporting the substrate.

13. The substrate processing module according to claim 12, the substrate processing module being a load-lock module and further comprising:
a gas injector configured to inject an inert gas into the interior space; a gas discharge unit configured to discharge gas from the interior space; a heat exchanger for temperature control of the substrate introduced into the interior space; and a gate valve opening or closing the gate.

14. The substrate processing module according to claim 12, wherein
the chamber includes a partition wall dividing the interior space to define a first interior space and a second interior space in an upward/downward direction, and
the lifting module is provided to each of the first interior space and the second interior space.

15. The substrate processing module according to claim 14, wherein the chamber includes two pairs of gates corresponding to the first interior space and the second interior space, respectively.

16. A substrate processing system comprising: at least one process module configured to perform substrate processing on a substrate at a preset process pressure; a load-lock module configured to deliver the substrate between the process module and an exterior at atmospheric pressure; and a transfer module configured to deliver the substrate between the process module and the load-lock module,
wherein at least one of the process module and the load-lock module is provided with the lifting module according to claim 1.
